(19) United States
(12) Patent Application Publication
(10) Pub. No.: US 2018/0175798 A1
(43) Pub. Date: Jun. 21, 2018

(54) AREA EFFICIENT ARCHITECTURE TO COMBINE OUTPUTS OF PARALLEL TRANSMIT SIGNAL PATHS

(71) Applicant: QUALCOMM Incorporated, San Diego, CA (US)

(72) Inventors: Jose Cabanillas, San Diego, CA (US); Marco Cassia, San Diego, CA (US); Wei Tai, San Diego, CA (US)

(21) Appl. No.: 15/413,019

(22) Filed: Jan. 23, 2017

Related U.S. Application Data
(60) Provisional application No. 62/437,472, filed on Dec. 21, 2016.

(51) Int. Cl. H03F 1/02; H03F 3/19; H03F 3/24

(52) U.S. Cl. CPC H03F 1/0277; H03F 3/19; H03F 3/245; H03F 2200/451; H04B 1/04; H03F 2200/267; H03F 2200/378; H03F 2203/21157; H03F 2200/171

(57) ABSTRACT

Methods, devices, apparatuses, and systems provide an efficient architecture for multi-mode amplifier modules by combining components of parallel transmit paths and reducing the number of total components used in amplifier modules. One such an amplifier module, including a first transmit path connected in parallel to a second transmit path between an input of the amplifier module and an intermediate node. The amplifier module further includes a common path connected to the intermediate node and an output of the amplifier module. The common path includes one or more shared components for a signal routed through either the first and second transmit paths.

### CROSS-REFERENCE TO RELATED APPLICATIONS

The present application for patent claims priority to U.S. Provisional Patent Application No. 62/437,472, entitled “AREA EFFICIENT ARCHITECTURE TO COMBINE OUTPUTS OF PARALLEL TRANSMIT SIGNAL PATHS”, filed Dec. 21, 2016

### BACKGROUND

In a wireless communication system, a transmitter may process (e.g., encode and modulate) data to generate output samples. The transmitter may further condition (e.g., convert to analog, filter, frequency up-convert, and amplify) the output samples to generate an output radio frequency (RF) signal. The transmitter may then transmit the output RF signal via a wireless channel to a receiver. The receiver may receive the transmitted RF signal and perform the complementary processing on the received RF signal. The receiver may condition (e.g., amplify, frequency down-convert, filter, and digitize) the received RF signal to obtain input samples. The receiver may further process (e.g., demodulate and decode) the input samples to recover the transmitted data.

The transmitter may support multiple modes and multiple frequency bands. Each mode may correspond to a different radio technology, and each frequency band may cover a different range of frequencies. The transmitter may include a number of power amplifiers to support the multiple modes and the multiple bands. For example, each power amplifier may support a specific mode on a specific band. A relatively large number of power amplifiers may then be used for the transmitter, which may increase size and cost of the transmitter.

### SUMMARY

One aspect of the present disclosure generally provides an amplifier module, including a first transmit path connected in parallel to a second transmit path between an input of the amplifier module and an intermediate node. The amplifier module further includes a common path connected to the intermediate node and an output of the amplifier module. The common path includes one or more shared components for a signal routed through either the first and second transmit paths.

In a further aspect, the present disclosure provides for a method including receiving a signal at an input of an amplifier module. The method further includes conveying, in a first mode of operation, the signal to a first transmit path and amplifying the signal. The method further includes conveying, in a second mode of operation, the signal to a second transmit path and amplifying the signal at a greater amplification than the first transmit path. The method further includes conveying, in both the first and second modes of operation, the signal amplified in the first or second transmit path through an intermediate node connected to a common path. The common path includes one or more components shared between both the first and second modes of operation. The method further includes outputting, after passing through the common path, the signal through an output of the amplifier module.

Furthermore, the present disclosure provides for a device that includes means for receiving a signal at an input of an amplifier module. The device further includes means for conveying, in a first mode of operation, the signal to a first transmit path and amplifying the signal. The device further includes means for conveying, in a second mode of operation, the signal to a second transmit path and amplifying the signal at a greater amplification the first transmit path. The device further includes means for conveying, in both the first and second modes of operation, the signal amplified in the first or second transmit path through an intermediate node connected to a common path. The common path includes one or more shared components between the first and second modes of operation. The device further includes means for outputting, after passing through the common path, the signal through an output of the amplifier module.

### BRIEF DESCRIPTION OF THE DRAWINGS

The accompanying drawings, which are incorporated herein and constitute part of this specification, illustrate exemplary embodiments of the disclosure, and together with the general description given above and the detailed description given below, serve to explain the features of the various embodiments.

FIG. 1 is a block diagram of a wireless communication device in accordance with various embodiments.

FIG. 2A illustrates an amplifier module with a plurality of transmit paths.

FIG. 2B illustrates another configuration of the amplifier module with a plurality of transmit paths.

FIG. 3A illustrates an amplifier module with a plurality of transmit paths that share a common path in accordance with various embodiments.

FIG. 3B illustrates another configuration of the amplifier module with a plurality of transmit paths that share a common path in accordance with various embodiments.

FIG. 4 is a flow diagram depicting a method for amplifying a signal according to multiple parallel transmit signal paths that share common components in accordance with various embodiments.

### DETAILED DESCRIPTION

Various embodiments will be described in detail with reference to the accompanying drawings. Wherever possible, the same reference numbers may be used throughout the drawings to refer to the same or like parts. Different reference numbers may be used to refer to different, same, or similar parts. References made to particular examples and implementations are for illustrative purposes, and are not intended to limit the scope of the disclosure or the claims.

The various embodiments disclosed herein relate to power amplifiers. More specifically, the embodiments relate to methods, systems, and devices for multi-mode power amplifiers. Amplifiers are commonly used in various electronic devices to provide signal amplification. For example, a wireless communication device such as a cellular phone may include a transmitter and a receiver for bi-directional communication. A transmitter may have multiple amplifiers to amplify a signal before transmitting the signal, providing multiple operating modes of the transmitter. These multiple amplifiers may be arranged in parallel to provide parallel transmit signal paths that each correspond to a different output power level, or can be used in combination to provide different output power levels. Additionally, a bypass mode may be provided that bypasses the amplifiers for an additional operating mode.

Therefore, an amplification module may have multiple power levels at which a signal can be amplified. Such an amplification module can use multiple sets of switches with each amplifier, power level, and/or bypass mode. In this way, the amplification module is configured such that the amplifiers support multiple modes, switching particular amplifiers on or off depending on the particular operating mode. For example, a group of switches may be used selectively route a signal fed to an input of an amplifier module through one of multiple transmit paths to an intermediate node as disclosed herein. The switches can also be used to selectively route a signal from the intermediate node to one of multiple, selectable outputs as disclosed herein.

Disclosed herein are systems and methods for reducing the complexity of an amplification module. The complexity may be reduced, for example, by using fewer switches and/or causing different signal transmit paths corresponding with different amplification levels to share some common circuitry on a common path, thereby reducing the number of circuit components used in an amplification module. In other words, certain components of each parallel path of an amplification module can be combined. By modifying a circuit in this way, both the cost and size of the circuit can be advantageously reduced.

Therefore, a multi-mode amplifier module capable of supporting multiple modes and multiple frequency bands is described herein. The amplification module may be used for various electronics devices such as wireless communication devices, cellular phones, personal digital assistants (PDAs), handheld devices, wireless modems, laptop computers, cordless phones, Bluetooth devices, consumer electronics devices, etc. One example of the use of an amplification module in a wireless communication device is described below. Various embodiments, as described herein, are directed to a multi-mode amplifier module. For example, an amplifier module may include a first signal transmit path including a first amplifier and a second amplifier. A second signal transmit path may include a third amplifier, or may include no amplifier at all. The first and second signal transmit paths may be connected in parallel and located or connected between an input of an amplifier module and an intermediate node of the amplifier module. A common path of the amplifier module may be located or connected between the intermediate node of the amplifier module and an output of the amplifier module, such that the common path includes one or more shared components for a signal routed through either the first and second transmit paths. Examples of shared components for signals routed through the common path may include switches, harmonic traps, or any other components. Shared components such as these will are discussed at length below, including how they function and are placed on a common transmit path.

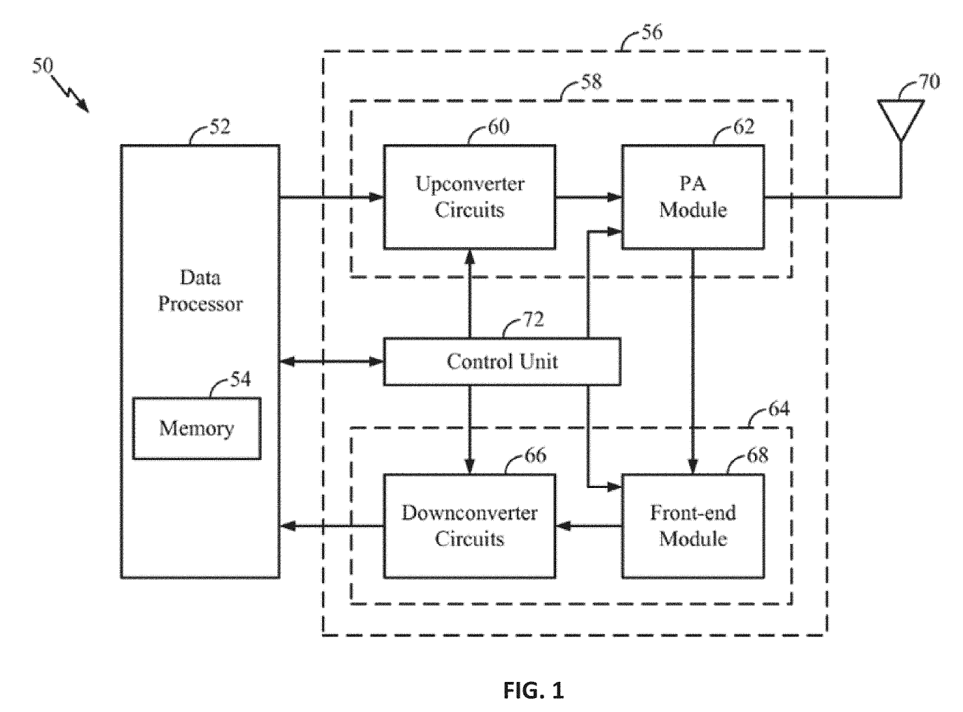

FIG. 1 shows a block diagram of an illustrative design of a wireless communication device 50. In this illustrative embodiment, wireless device 50 includes a data processor 52 and a transceiver 56. Transceiver 56 includes a transmitter 58 comprising up-converter circuits 60 and an amplifier module 62. Transceiver 56 further includes a receiver 64 comprising a front-end module 68 and down-converter circuits 66. In general, wireless device 50 may include any number of transmitters and any number of receivers for any number of communication systems and any number of frequency bands.

In the transmit path, data processor 52 may process data to be transmitted and provide an output baseband signal to transmitter 58. Within transmitter 58, up-converter circuits 60 may process (e.g., amplify, filter, and frequency up-convert) the output baseband signal and provide an input RF signal. Up-converter circuits 60 may include amplifiers, filters, mixers, etc. The amplifier module 62 may amplify the input RF signal to obtain the desired output power level and provide an output RF signal, which may be transmitted via an antenna 70. The amplifier module 62 may include driver amplifiers, power amplifiers, switches, etc., as described below.

In the receive path, antenna 70 may receive RF signals transmitted by base stations and/or other transmitter stations and may provide a received RF signal, which may be routed via the amplifier module 62 and provided to receiver 64. Within receiver 64, front-end module 68 may process (e.g., amplify and filter) the received RF signal and provide an amplified RF signal. Front-end module 68 may include duplexers, low noise amplifiers (LNA), etc. Down-converter circuits 66 may further process (e.g., frequency down-convert, filter, and amplify) the amplified RF signal and provide an input baseband signal to data processor 52. Down-converter circuits 66 may include mixers, filters, amplifiers, etc. Data processor 52 may further process (e.g., digitize, demodulate, and decode) the input baseband signal to recover transmitted data.

A control unit 72 may receive control information from data processor 52 and may generate controls for the circuits and modules in transmitter 58 and receiver 64. Data processor 52 may also provide controls directly to the circuits and modules in transmitter 58 and receiver 64. In any case, the controls may direct the operation of the circuits and modules to obtain the desired performance.

FIG. 1 shows an illustrative design of transmitter 58 and receiver 64. In general, the conditioning of the signals in transmitter 58 and receiver 64 may be performed by one or more stages of amplifiers, filters, mixers, etc. These circuit blocks may be arranged in various configurations. All or a portion of transmitter 58 and all or a portion of receiver 64 may be implemented on one or more analog integrated circuits (ICs), one or more RF ICs (RFICs), one or more mixed-signal ICs, etc. For example, the amplifier module 62 may be implemented on one RFIC, and up-converter circuits 60 and down-converter circuits 66 may be implemented on another RFIC.

Data processor 52 may perform various functions for wireless device 50, e.g., processing for data being transmitted or received. A memory 54 may store program codes and data for data processor 52. Data processor 52 may be implemented on one or more application specific integrated circuits (ASICs) and/or other ICs.

Wireless device 50 may support multiple modes and multiple bands. The amplifier module 62 may be designed to support all of the modes and bands supported by wireless device 50. The multiple modes may correspond to different radio technologies such as Code Division Multiple Access (CDMA) lx, Wideband CDMA (WCDMA), Global System for Mobile Communications (GSM), Long Term Evolution (LTE), Wireless Local Area Network (WLAN), etc. Each mode may correspond to a particular radio technology, which may utilize frequency division duplexing (FDD) or time division duplexing (TDD). For FDD, different frequency channels are used for the downlink and uplink, and a duplexer may be used to route an output RF signal from a transmitter to an antenna and to route a received RF signal from the antenna to a receiver. For TDD, the same frequency channel is used for both the downlink and uplink, and a switch may be used to couple the transmitter to the antenna some of the time and to couple the receiver to the antenna some other time.

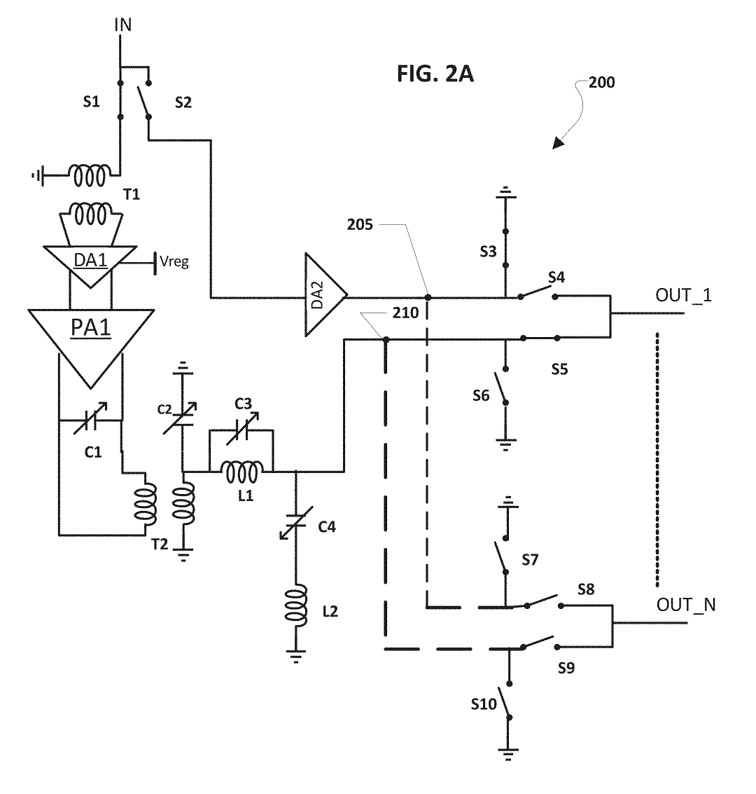

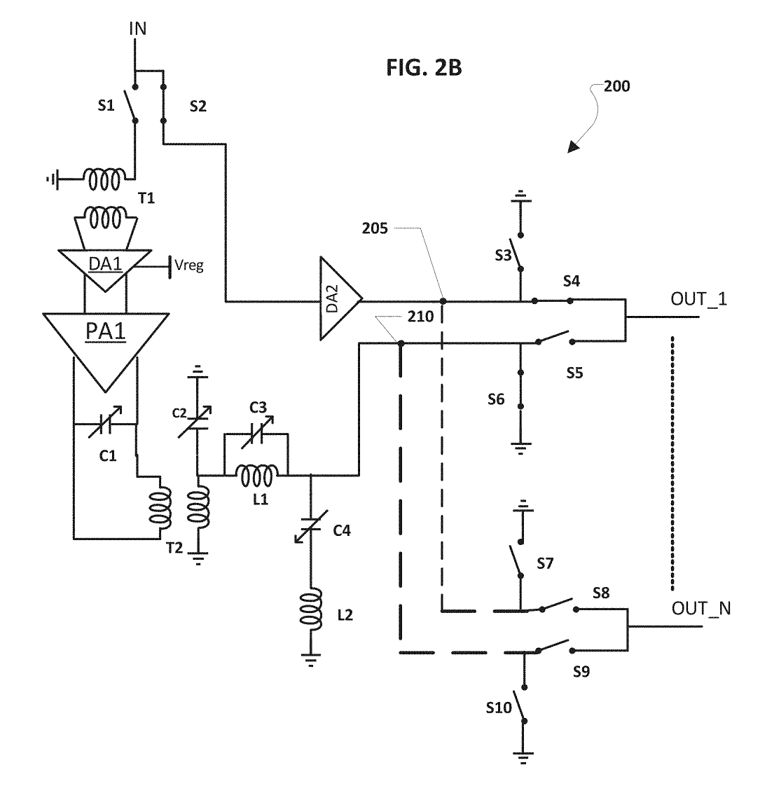

FIG. 2A illustrates an amplifier module 200 with a plurality of transmit paths. In particular, the amplifier module includes an input IN at which a signal is input to be amplified. At the input, the signal can be sent down a first transmit path (in this example, a low power or bypass operating mode) if switch S1 is closed, while switch S2 is open. Conversely, the signal can be sent down a second transmit path (in this example, a medium or high power operating mode) if switch S2 is closed, while switch S1 is open (as demonstrated in FIG. 2B). In the first operating mode using the first transmit path the signal is sent through transformers T1 and T2; a driver amplifier DA1; a power amplifier PA1; capacitances C1, C2, C3, and C4; and inductances L1 and L2. In passing through such components, the signal can be amplified according to a specific operating mode. Capacitance C3 and L1 represent a harmonic filter or trap to filter or remove harmonics and/or other noise from the signal. Capacitance C4 and L2 also represent a harmonic filter or trap. Once the signal is amplified through the first transmit path, the signal can be output at OUT_1. To do so, switches S3 and S5 are closed, and switches S4 and S6 are open, as shown in FIG. 2A.

In various embodiments, an amplifier module may also have additional outputs OUT_N. There is no limit to the number of outputs an amplifier module may have. The outputs may, for example, correspond to different frequency bands, functions of a wireless device, antennas, etc. The additional output OUT_N shown in FIG. 2A is connected at nodes 205 and 210. If, for example, the output from the first transmit path was to output at OUT_N, then switches S3, S6, S7, and S9 would be closed, while switches S4, S5, S8, and S10 would be open, allowing the signal to flow through the first transmit path, through the node 210, through the switch S9 and out the output OUT_N. Accordingly, many switches are opened and closed depending on which output the amplified signal is supposed to be output from. In FIG. 2A, with only two transmit paths and two outputs shown, there are ten switches used.

FIG. 2B illustrates another configuration of the amplifier module 200 with a plurality of transmit paths. In the second operating mode, when switch S2 is closed and switch S1 is open, the signal received at IN is sent down the second transmit path, through a driver amplifier DA2. As shown in FIG. 2B, the signal is then output at OUT_1 by opening switches S3 and S5, while closing switches S4 and S6. Similar to the first transmit path described above with respect to FIG. 2A, additional outputs OUT_N may exist. For example, if the signal from the second transmit path was output at OUT_N, the signal would go through the node 205 and switch S8. To do so the amplifier module would open switches S4, S5, S7, and S9, while closing switches S3, S6, S8, and S10. Again, switching between operating modes/signal transmit paths and outputs is done by changing the position of many switches, which are used to selectively route a signal fed to an input of an amplifier module through one of multiple transmit paths to an intermediate node as disclosed herein. The switches can also be used to selectively route a signal from the intermediate node to one of multiple, selectable outputs as disclosed herein.

Accordingly, amplifier architectures may suffer from lower performance and increasing complexity as the number of required frequency bands (outputs and signal transmit paths) increases. Because power is needed to operate each switch, the efficiency of an amplifier module would be increased if the number of switches were reduced. Additionally, the footprint or size of the amplifier module would also be reduced if the number of switches were reduced. Accordingly, disclosed herein is a simpler, smaller, more efficient, and less costly amplifier module that reduces the number of switches used, and allows for the sharing of some circuitry between different signal transmit paths, such as harmonic traps or filtering.

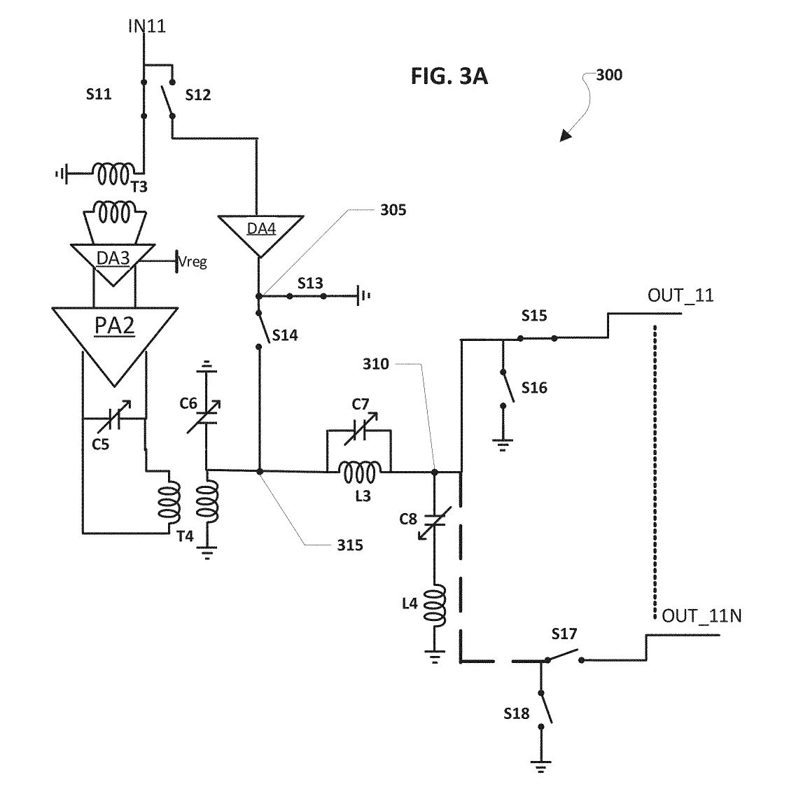

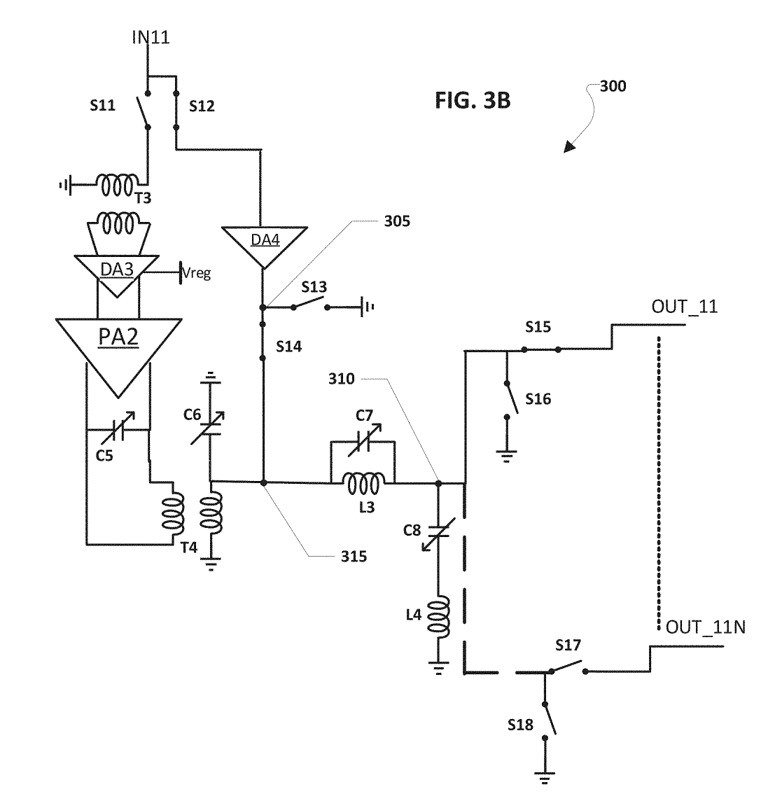

FIG. 3A illustrates an amplifier module 300 with a plurality of transmit paths that share a common path in accordance with various embodiments. The amplifier module 300 includes an input IN11 connected to a switch S11 and a switch S12. S11 is the beginning of a first signal transmit path (a medium or high power amplifier operating mode). S12 is the beginning of a second signal transmit path (a low power or bypass amplifier operating mode). The first signal transmit path includes a transformer T3 connected to the switch S11, a driver amplifier DA3 connected to the transformer T3, and a power amplifier PA2 connected to the driver amplifier DA3. The first signal transmit path also includes a second transformer T4, that has capacitances C5 and C6 connected across the primary and secondary windings, respectively. The secondary winding of the transformer T4 is also connected to an intermediate node 315 that connects the end of the first signal transmit path with the end of a second transmit signal path and the beginning of a common path share by the first and second transmit paths.

The second signal transmit path includes the switch S12 connected to a driver amplifier DA4. The output of DA4 is connected to an intermediate node 305. A switch S13 is connected to the node 305 and ground. Another switch S14 is connected to the intermediate node 305 and the intermediate 315, connecting the second signal transmit path to the common path. When a signal is passed through the second signal transmit path (as shown and discussed with respect to FIG. 3B), switch S14 is closed and switch S13 is open. When a signal is passed through the first signal transmit path, as shown in FIG. 3A, the switch S13 is closed, and the switch S14 is open.

The common path includes harmonic traps or filters made up of capacitances C7 and C8, as well as inductances L3 and L4. In particular, C7 and L3 are connected in parallel to each other and in series with the intermediate node 315 and an intermediate node 310. C8 and L4 are connected in series, with the C8 being connected to the intermediate node 310 and L4 being connected to ground. Accordingly, signal may be passed through, in a high or medium power operating mode, switch S11 and the first signal transmit path, the intermediate node 315, the harmonic traps of the common path and the intermediate node 310, and out an output OUT_11. In order to output the amplified signal at OUT_11, switch S15 is closed and switch S16 is open. If additional outputs N are added, only two switches are used per output. As is evident comparing FIG. 3A to FIG. 2A, fewer switches are used in the amplifier module 300, thereby reducing the cost, complexity, and power usage of the amplifier module 300. Compared to the ten switches of FIG. 2A, FIG. 3A only has eight switches. The benefits are more pronounced as additional outputs N are added. In particular, the amplifier module 300 has 2*N−2 fewer switches than the amplifier module 200. For example, if there are 4 outputs, then then amplifier module 300 would have six fewer switches than module 200. Fewer switches result in a smaller overall circuit, and fewer switches having to be switched each time a different operating mode/signal transmit path is used. Additionally, the common path of the amplifier module 300 allows both the first and second signal transmit paths to share the harmonic traps of the common path. As compared to the amplifier module 200, the second transmit path had no harmonic traps. If the second transmit path of the amplifier module 200 had harmonic traps, they would be added to that signal path separately. Advantageously, the two modes of the amplifier module 300 can share the harmonic trap circuitry without duplicating it.

In the amplifier module 300, the capacitances C5 and C6 can also be set such that an impedance of the first transmit path reduces loading of the first transmit path to the second transmit path. That is, when the low power or bypass mode is being used (DA4), it is undesirable for any signal to pass from the second transmit path, through the intermediate node 315, and into the first transmit path (C6, T4, C5, PA2, etc.). Accordingly, the capacitances C5 and C6 can be set or tuned to reduce such an occurrence. In various embodiments, C5 and C6 may be used or tuned to be part of an output matching network for the bypass amplifier DA4. Additionally, the transformer T4 may be used as a tuning element to help prevent signal from passing backward into the first signal transmit path.

In various alternative embodiments, additional signal transmit paths (or amplifier operating modes) may be added to the amplifier module 300. For example, additional signal transmit paths may be added parallel to the first and second signal transmit paths by connecting an additional transmit path to the input IN11 and the intermediate node 315.

FIG. 3B illustrates another configuration of the amplifier module 300 with a plurality of transmit paths that share a common path in accordance with various embodiments. In particular, FIG. 3B demonstrates the state of the switches when a low power or bypass mode is used (second signal transmit path). The switch S12 is closed and the switch S11 is open, so that a signal from IN11 can pass to the driver amplifier DA4, and the intermediate node 305. Further, switch S13 is open and switch S14 is closed so that the amplified signal can pass through the intermediate node 315, through the common path including the harmonic traps and the intermediate node 310, and output OUT_11 through switch S15. Similarly, to the discussion above with respect to FIG. 3A, the signal from the low power or bypass path may also be output through any number N of outputs by adjusting the switches (e.g., switches S15, S16, S17, S18) accordingly.

As discussed herein, additional output power levels/signal paths may also be supported by adding paths in parallel to the existing first and second signal paths. For example, different amplifiers may be selected for each mode/band configuration of a wireless device and/or each output power level. For example, a driver amplifier (DA) and a power amplifier (PA) a may be selected for the medium output power level for GSM, as shown in the first signal transmit path of the amplifier module 300. The switches and the amplifiers may be operated based on how the output power levels are defined.

In various embodiments, the power amplifiers and driver amplifiers may be configured differently. For example, each amplifier used in an amplifier module may have a fixed gain or a variable gain. In an illustrative embodiments, each amplifier may provide a fixed gain when selected. Power control may be achieved by (i) selecting a proper output power level for coarse gain adjustment and/or (ii) varying a digital gain within data processor or an analog gain within upconverter circuits for fine gain adjustment. The digital gain or the analog gain may cover a range of gains for each output power level.

In other illustrative embodiments, a driver amplifier may have a programmable gain, which may be selected based on a gain control. A driver amplifier may have 2L gain steps of X dB/step, for example, and a suitable gain step may be selected with an L-bit gain control. For example, L may be equal to 4 and X may be equal to 1. A driver amplifier may then have 16 gain steps spaced apart by 1 dB, and one gain step may be selected with a 4-bit gain control. Fewer or more gain steps may also be supported. Power control may be achieved by selecting a proper output power level, selecting a proper gain for driver amplifier, and varying a digital gain within a data processor or an analog gain within upconverter circuits.

In various embodiments, a power amplifier (PA) may include any number of driver amplifiers and any number of power amplifiers. The driver amplifiers of a PA may have the same or different gains. A PA may have the same or different gains and the same or different maximum output power levels. A PA module may also support any number of modes and any number of bands. A number of mode/band configurations may be defined. Each mode/band configuration may cover one or more modes and one or more bands. For example, the CDMA configuration described above may cover CDMA 1× and WCDMA for one band, and the GSM configuration may cover GSM for multiple bands. Each mode/band configuration may be associated with a set of amplifiers that may be used for that mode/band configuration. Any number of output power levels may be supported for each mode/band configuration. Each output power level may be associated with zero, one, or more amplifiers being operational to obtain the desired output power level. Additional switches may be implemented and operated to select the enabled amplifiers, if any, and to bypass the unselected amplifiers, e.g., as described above.

The multi-mode amplifier module described herein therefore provides certain advantages. Driver amplifiers, power amplifiers, matching circuits, and switches may be implemented in a single package with a small footprint. This allows for a highly integrated low-cost multi-mode, multi-band wireless device. Additionally, circuitry such as harmonic traps and filters may be shared by different modes on a common path to reduce the number of amplifiers needed to implement all modes and bands supported by the wireless device. In various embodiments, other circuitry may exist on a common path and shared by different modes/paths. For example, driver amplifiers and power amplifiers may be shared by different modes by placing them on the common path. As an example, if DA3 and DA4 of the amplifier module 300 were the same, a single DA may be relocated to the common path, allowing for even further reduced circuitry used to implement the multi-mode amplifier module. In another example, power amplifiers may be designed for different bands for CDMA and may be reused for GSM to avoid a separate power amplifier for GSM. In other examples, circuitry including amplifiers, filters, transformers, or any other component may be located at an output, such as any of outputs OUT_11 to OUT_11N of the amplifier module 300. In this way, specific circuitry could be selected and combined with the modes already existing in the amplifier module 300 using the switches of the amplifier module 300 to select which output to send a signal to. Additionally, fewer switches are used to select different combinations of amplifiers for different output power levels in order to achieve high efficiency at different output power levels for a given mode/band configuration. As another possible advantage, any gains and possible matching circuits used at outputs of the amplifier module 300 may be configurable to achieve high efficiency across different modes, bands, and output power levels. Additionally, filtering for harmonic rejection may be integrated with impedance matching to reduce component count and facilitate integration, and switches to implement antenna switching may also be integrated to avoid a separate switchplexer module.

The various embodiments disclosed herein provide for dedicated transmit paths for power and/or bypass modes. Accordingly, each path may be optimized accordingly. Further, various embodiments can provide for inter-stage impedance matching based on switchable transformers, which may result in wider bandwidth without adding any devices. Therefore, the output power can be tuned to meet long term evolution (LTE) requirements without hurting low-power mode performance. Additionally, various embodiments can include multi-port transmitter switch devices, which can be split into two output ports of a transformer, thus resulting in the substantial reduction of insertion loss compared to conventional amplifier switches.

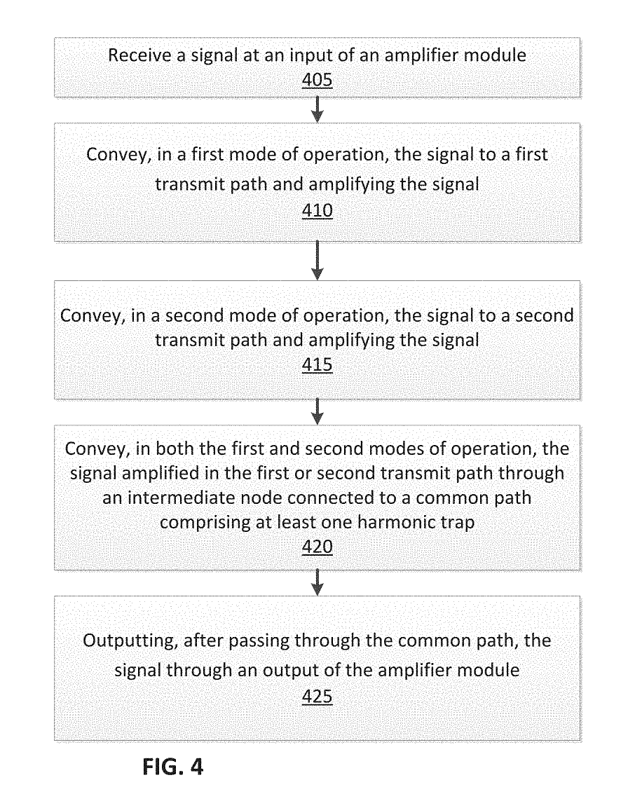

FIG. 4 is a flow diagram depicting a method 400 for amplifying a signal according to multiple parallel transmit signal paths that share common components in accordance with various embodiments. In an operation 405, an amplifier module receives a signal at an input of an amplifier module. In an operation 410, the amplifier module conveys, in a first mode of operation, the signal to a first transmit path and amplifying the signal. In an operation 415, the amplifier module conveys, in a second mode of operation, the signal to a second transmit path and amplifying the signal. Amplification of the signal in the second transmit path, in this example, is greater than amplification of the signal in the first transmit path. For example, the second transmit path here may be the transmit path with DA3 and PA2 of amplifier module 300 in FIGS. 3A and 3B, while the first transmit path corresponds to DA4 and a lower amplification.

In an operation 420, the amplifier module conveys, in both the first and second modes of operation, the signal amplified in the first or second transmit path through an intermediate node connected to a common path comprising at least one harmonic trap. In an operation 425, the amplifier module outputs, after passing through the common path, the signal through an output of the amplifier module, as disclosed herein throughout.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof

The PA module described herein may be implemented on an IC, an analog IC, an RFIC, a mixed-signal IC, an ASIC, a printed circuit board (PCB), an electronics device, etc. The PA module may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), etc.

An apparatus implementing the amplifier module described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

The previous description of the disclosed various embodiments is provided to enable any person skilled in the art to make or use the claims. Various modifications to these various embodiments will be readily apparent to those skilled in the art, and the generic principles defined herein may be applied to other embodiments without departing from the spirit or scope of the claims. Thus, the claims are not intended to be limited to the various embodiments shown herein but is to be accorded the widest scope consistent with the principles and novel features disclosed herein.

The various embodiments illustrated and described are provided merely as examples to illustrate various features of the claims. However, features shown and described with respect to any given embodiment are not necessarily limited to the associated embodiment and may be used or combined with other embodiments that are shown and described. Further, the claims are not intended to be limited by any one example embodiment.

The foregoing method descriptions and the process flow diagrams are provided merely as illustrative examples and are not intended to require or imply that the steps of various embodiments must be performed in the order presented. As will be appreciated by one of skill in the art the order of steps in the foregoing embodiments may be performed in any order. Words such as “thereafter,” “then,” “next,” etc. are not intended to limit the order of the steps; these words are simply used to guide the reader through the description of the methods. Further, any reference to claim elements in the singular, for example, using the articles “a,” “an” or “the” is not to be construed as limiting the element to the singular.

The various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present method and apparatus.

The hardware used to implement the various illustrative logics, logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Alternatively, some steps or methods may be performed by circuitry that is specific to a given function.

In some various embodiments, the functions described may be implemented in hardware, software, firmware, or any combination thereof. If implemented in software, the functions may be stored as one or more instructions or code on a non-transitory computer-readable storage medium or non-transitory processor-readable storage medium. The steps of a method or algorithm disclosed herein may be embodied in a processor-executable software module which may reside on a non-transitory computer-readable or processor-readable storage medium. Non-transitory computer-readable or processor-readable storage media may be any storage media that may be accessed by a computer or a processor. By way of example but not limitation, such non-transitory computer-readable or processor-readable storage media may include RAM, ROM, EEPROM, FLASH memory, CD-ROM or other optical disk storage, magnetic disk storage or other magnetic storage devices, or any other medium that may be used to store desired program code in the form of instructions or data structures and that may be accessed by a computer. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above are also included within the scope of non-transitory computer-readable and processor-readable media. Additionally, the operations of a method or algorithm may reside as one or any combination or set of codes and/or instructions on a non-transitory processor-readable storage medium and/or computer-readable storage medium, which may be incorporated into a computer program product.

The preceding description of the disclosed embodiments is provided to enable any person skilled in the art to make or use the present method and apparatus. Various modifications to these embodiments will be readily apparent to those skilled in the art, and the generic principles defined herein may be applied to some embodiments without departing from the spirit or scope of the method and apparatus. Thus, the present method and apparatus is not intended to be limited to the embodiments shown herein but is to be accorded the widest scope consistent with the following claims and the principles and novel features disclosed herein.

1. An amplifier module, comprising:
a first transmit path connected in parallel to a second transmit path between an input of the amplifier module and an intermediate node; and
a common path connected to the intermediate node and an output of the amplifier module, the common path comprising one or more shared components for a signal routed through either the first and second transmit paths.

2. The amplifier module of claim 1, wherein the one or more shared components comprise at least one harmonic trap.

3. The amplifier module of claim 2, wherein the harmonic trap comprises a capacitance and an inductance connected in parallel between the intermediate node and the output of the amplifier module.

4. The amplifier module of claim 2, wherein the harmonic trap comprises a capacitance and an inductance connected in series between the common path and a ground of the amplifier module.

5. The amplifier module of claim 1, wherein the first transmit path comprises a first switch connected in the first transmit path and a second switch connected to the first transmit path and a ground of the amplifier module.

6. The amplifier module of claim 1, further comprising a plurality of switches configured to selectively route a signal fed to the input through one of the first and second transmit paths to the intermediate node.

7. The amplifier module of claim 6, wherein the output comprises a plurality of selectable outputs; and
wherein the plurality of switches are further configured to selectively route the signal from the intermediate node to one of the plurality of outputs.

8. The amplifier module of claim 6, wherein the first transmit path and the second transmit path are configured to amplify an input signal at different output power levels.

9. The amplifier module of claim 1, wherein the second transmit path further comprises at least one capacitance.

10. The amplifier module of claim 9, wherein the capacitance is connected in parallel across a primary side of at least one transformer in the first transmit path.

11. The amplifier module of claim 9, wherein the capacitance is connected in parallel across a secondary side of at least one transformer in the first transmit path.

12. The amplifier module of claim 1, wherein at least one of the first and second transmit paths comprise at least one driver amplifier.

13. The amplifier module of claim 1, wherein at least a portion of the plurality of switches comprise a first switch, a second switch, a third switch, and a driver amplifier wherein:
the first switch is connected to the input of the amplifier module and the driver amplifier,
the driver amplifier is connected to the first switch and a second intermediate node,
the second switch is connected to the second intermediate node and a ground of the amplifier module, and
the third switch is connected to the second intermediate node and the common path.

14. The amplifier module of claim 13, wherein in a first mode of operation of the amplifier module, the first switch is closed, the second switch is open, and the third switch is closed to pass the signal through the first transmit path.

15. The amplifier module of claim 14, wherein the second transmit path comprises a fourth switch connected to the input of the amplifier module and, in a second mode of operation of the amplifier module, the first switch is open, the second switch is closed, the third switch is open, and the fourth switch is closed to pass the signal through the second transmit path.

16. The amplifier module of claim 2, wherein the harmonic trap is further connected to the intermediate node and a second intermediate node that connects the harmonic trap to the output of the amplifier module.

17. The amplifier module of claim 16, wherein the output of the amplifier module comprises a first output and a second output, wherein each of the first and second outputs are connected to the second intermediate node.

18. The amplifier module of claim 17, wherein the first output comprises a fifth switch and a sixth switch, and wherein:
the fifth switch is connected to the second intermediate node and the first output,
the sixth switch is connected to the second intermediate node and a ground of the amplifier module, and
the fifth switch is closed and the sixth switch is open to output the signal to the first output.

19. The amplifier module of claim 18, wherein the second output comprises a seventh switch and an eighth switch, and wherein:
the seventh switch is connected to the second intermediate node and the second output,
the eighth switch is connected to the second intermediate node and the ground,
the fifth switch is open, the sixth switch is closed, the seventh switch is closed, and the eighth switch is open to output the signal to the second output, and
the seventh switch is open and the eighth switch is closed to output the signal to the first output.

20. The amplifier module of claim 19, wherein the output of the amplifier module further comprises a plurality of additional outputs that are each connected to the second intermediate node.

21. The amplifier module of claim 1, further comprising at least one additional transmit path configured to amplify the signal and connected in parallel with the first and second transmit paths across the input and the intermediate node.

22. A method comprising:
receiving a signal at an input of an amplifier module;
conveying, in a first mode of operation, the signal to a first transmit path and amplifying the signal;
conveying, in a second mode of operation, the signal to a second transmit path and amplifying the signal at a greater amplification than the first transmit path;
conveying, in both the first and second modes of operation, the signal amplified in the first or second transmit path through an intermediate node connected to a common path comprising one or more components shared between both the first and second modes of operation; and
outputting, after passing through the common path, the signal through an output of the amplifier module.

23. The method of claim 22, wherein conveying the signal to the first transmit path in the first mode comprises:
closing a first switch of the first transmit path connected to the input of the amplifier module; and
opening a second switch of the second transmit path connected to the input of the amplifier module.

24. The method of claim 23, wherein the first transmit path comprises a signal amplifier connected to the first switch and a second intermediate node, and wherein conveying the signal to the first transmit path in the first mode further comprises:
opening the third switch connected to the second intermediate node and a ground of the amplifier module; and
closing the fourth switch connected to the second intermediate node and the intermediate node.

25. The method of claim 24, wherein conveying the signal to the second transmit path in the second mode comprises:
opening the first switch;
closing the second switch;
closing the third switch; and
opening the fourth switch.

26. The method of claim 22, wherein outputting the signal through the output of the amplifier module comprises outputting the signal to one of a plurality of outputs, wherein:
a first output comprises a first switch connected to the common path and the first output, and the further comprises a second switch connected to the common path and a ground of the amplifier module; and
a second output comprises a third switch connected to the common path and the second output, and the further comprises a fourth switch connected to the common path and the ground.

27. The method of claim 26, wherein outputting the signal through the first output comprises:
closing the first switch;
opening the second switch;
opening the third switch; and
closing the fourth switch.

28. The method of claim 26, wherein outputting the signal through the second output comprises:
opening the first switch;
closing the second switch;
closing the third switch; and
opening the fourth switch.

29. The method of claim 22, wherein the second transmit path comprises at least one transformer and at least one capacitance connected in parallel across a primary or secondary side of the at least one transformer, and wherein the method further comprises setting the capacitance such that an impedance of the second transmit path reduces loading of the second transmit path to the first transmit path.

30. A device, comprising:
means for receiving a signal at an input of an amplifier module;
means for conveying, in a first mode of operation, the signal to a first transmit path and amplifying the signal;
means for conveying, in a second mode of operation, the signal to a second transmit path and amplifying the signal at a greater amplification the first transmit path;
means for conveying, in both the first and second modes of operation, the signal amplified in the first or second transmit path through an intermediate node connected to a common path comprising one or more shared components between the first and second modes of operation; and
means for outputting, after passing through the common path, the signal through an output of the amplifier module.
